(19) United States
(12) Patent Application Publication
(10) Pub. No.: US 2013/0044544 A1
(43) Pub. Date: Feb. 21, 2013

(54) NONVOLATILE MEMORY DEVICE

(71) Applicants: Yasuhiro SHIINO, Kanagawa-ken (JP); Manabu SAKANIWA, Kanagawa-ken (JP); Shigefumi IRIEDA, Kanagawa-ken (JP); Koki UENO, Kanagawa-ken (JP)

(72) Inventors: Yasuhiro SHIINO, Kanagawa-ken (JP); Manabu SAKANIWA, Kanagawa-ken (JP); Shigefumi IRIEDA, Kanagawa-ken (JP); Koki UENO, Kanagawa-ken (JP)

(73) Assignee: Kabushiki Kaisha Toshiba, Tokyo (JP)

(21) Appl. No.: 13/413,067

(22) Filed: Mar. 6, 2012

(30) Foreign Application Priority Data
Aug. 19, 2011 (JP) 2011-179624

(51) Int. Cl. G11C 16/10; G11C 16/04

(52) U.S. Cl. 365/185.17; 365/185.19

(57) ABSTRACT

According to one embodiment, a nonvolatile memory device includes a circuit and a memory cell. The circuit outputs a program voltage. The memory cell is programmed data by being applied the program voltage. The circuit outputs the program voltage so as to satisfy the following formulae, in the case of repeating an output of the program voltage n times (n is an integer not less than 3), when the program voltage in the k-th output (k is an integer not less than 2 and not greater than n) is set to Vpgm(k), a constant voltage is set as Δv1, a time in which the k-th output is continued is set to Tpgm(k), and a constant time is set as Δt1.

Vpgm(k)=Vpgm(k−1)+Δv1

Tpgm(k)=Tpgm(k−1)+Δt1

### CROSS-REFERENCE TO RELATED APPLICATIONS

This application is based upon and claims the benefit of priority from the prior Japanese Patent Application No. 2011-179624, filed on Aug. 19, 2011; the entire contents of which are incorporated herein by reference.

### FIELD

Embodiments described herein relate generally to a nonvolatile memory device.

### BACKGROUND

Conventionally, in a NAND type flash memory device, a charge accumulation layer (e.q. a floating electrode or an insulating film with charge trap layer) is provided between an active area and a word line, and a memory cell including at least one of charge accumulation layer is formed at each closest point of the active area and the word line. Furthermore, by applying a program voltage between the active area and the word line, electrons are injected from the active area to the charge accumulation layer, and a threshold value of a transistor constituting the memory cell is changed, thereby programming data to the memory cell. At this time, it is difficult to sufficiently change threshold values of all the memory cells to which data is to be programmed by one time application of the program voltage. Therefore, after the one time application of the program voltage, a verification of the memory cell is performed. Then, the program voltage is applied again to a memory cell whose change in the threshold value is insufficient. At this time, the program voltage is set slightly higher than the voltage previously applied. After that, the verification is performed again. As described above, the programming of data to the memory cell is performed by repeating the application of the program voltage and the verification.

However, because of a limited capacity of a charge pump for generating a program voltage, sufficient time is devoted to increase the voltage applied between the active area and the word line, to a program voltage. For this reason, a part of the time in which the voltage is output between the active area and the word line is devoted to increase the voltage, and a program voltage is output only in the rest of the time. Furthermore, the time required for increasing the voltage becomes longer when the program voltage becomes higher, in case of using the charge pump of the same capacity. Moreover, in many cases, the time in which an output of the voltage is continued is set such that the program voltage is output over a sufficient period of time in the case of the highest program voltage. For this reason, the program voltage is applied to the memory cell over an excessively long period of time in the case of an initial output of a relatively low program voltage, because the time devoted to increase the voltage is short in this case. Therefore, the time of an overall programming operation becomes unnecessarily long, which disturbs the realization of a higher speed operation of the NAND type memory flash.

### BRIEF DESCRIPTION OF THE DRAWINGS

FIG. 1 is a block diagram illustrating a nonvolatile memory device according to a first embodiment;

FIG. 2 is a chart diagram illustrating a programming operation of the nonvolatile memory device according to the first embodiment;

FIG. 3 is a chart diagram showing a specific example of a profile of one pulse of an AA-WL voltage;

FIG. 4 is a chart diagram illustrating an operation of the nonvolatile memory device according the first embodiment;

FIG. 5 is a chart diagram illustrating a programming operation of a nonvolatile memory device according to a comparative example of the first embodiment;

FIG. 6 is a chart diagram illustrating a programming operation of a nonvolatile memory device according to a modified example of the first embodiment;

FIG. 7 is a flowchart illustrating an operation of the nonvolatile memory device according to the modified example of the first embodiment;

FIG. 8 is a chart diagram illustrating a programming operation of a nonvolatile memory device according to a second embodiment;

FIG. 9A is a flowchart illustrating an operation of the nonvolatile memory device according to the second embodiment;

FIG. 9B is a graph illustrating programming operation of the nonvolatile memory device according to the embodiment, in which a horizontal axis indicates threshold voltage and a vertical axis indicates number of memory cells;

FIG. 9C is a chart diagram illustrating a programming operation of the nonvolatile memory device according to the embodiment, in which a horizontal axis indicates time and a vertical axis indicates voltage;

FIG. 10A is a flowchart diagram illustrating an operation of the nonvolatile memory device according to a modified example of the second embodiment;

FIG. 10B is a chart diagram illustrating a programming operation of a nonvolatile memory device according to t modified example of the embodiment.

FIG. 11 is a chart diagram illustrating a programming operation of a nonvolatile memory device according to a third embodiment;

FIG. 12 is a block diagram illustrating a nonvolatile memory device according to a fourth embodiment;

FIG. 13 is a chart diagram illustrating a programming operation of the nonvolatile memory device according to the fourth embodiment;

FIG. 14 is a block diagram illustrating a nonvolatile memory device according to a modified example of the fourth embodiment;

FIG. 15 is a chart diagram illustrating a programming operation of the nonvolatile memory device according to a fifth embodiment;

FIG. 16 is a chart diagram illustrating a programming operation of the nonvolatile memory device according to a sixth embodiment;

FIG. 17 is a chart diagram illustrating a programming operation of the nonvolatile memory device according to a seventh embodiment; and

FIG. 18 is a chart diagram illustrating a programming operation of the nonvolatile memory device according to an eighth embodiment.

### DETAILED DESCRIPTION

In general, according to one embodiment, a nonvolatile memory device includes a circuit and a memory cell. The circuit outputs a program voltage. The memory cell is programmed data by being applied the program voltage. The circuit outputs the program voltage so as to satisfy the following formulae, in the case of repeating an output of the program voltage n times (n is an integer not less than 3), when the program voltage in the k-th output (k is an integer not less than 2 and not greater than n) is set to Vpgm(k), a constant voltage is set as Δv1, a time in which the k-th output is continued is set to Tpgm(k), and a constant time is set as Δt1.

Vpgm(k)=Vpgm(k−1)+Δv1

Tpgm(k)=Tpgm(k−1)+Δt1

Embodiments of the invention will now be explained with reference to the drawings.

First, a first embodiment will be explained.

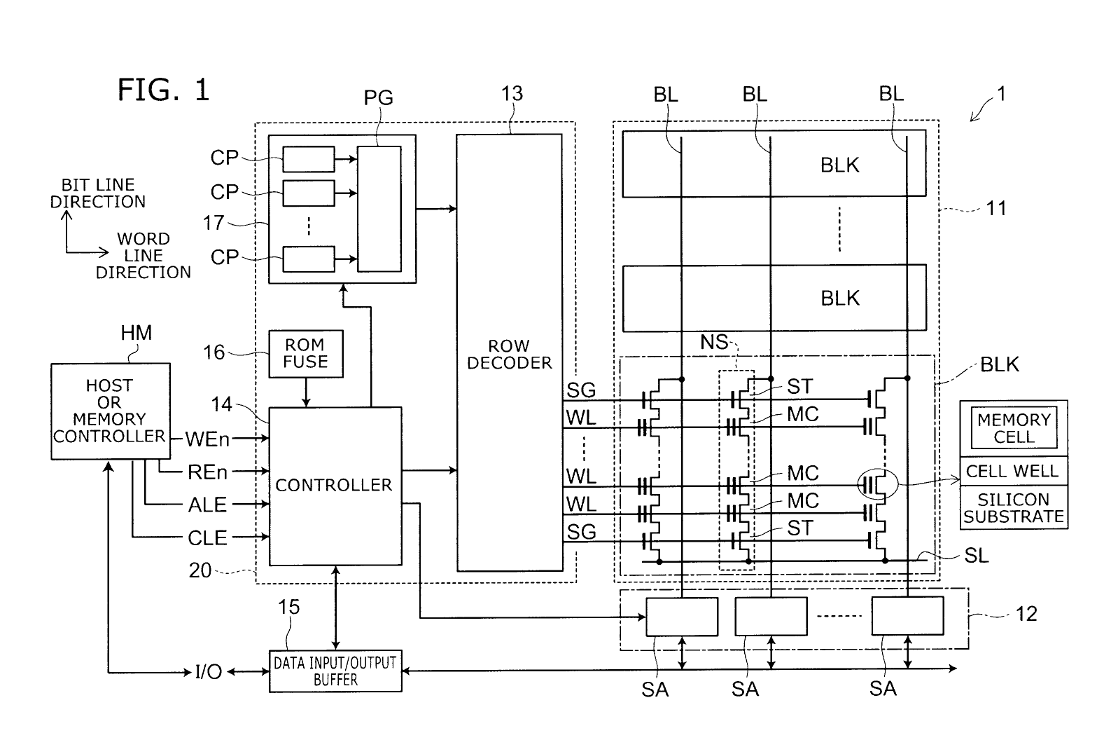

FIG. 1 is a block diagram illustrating a nonvolatile memory device according to the embodiment;

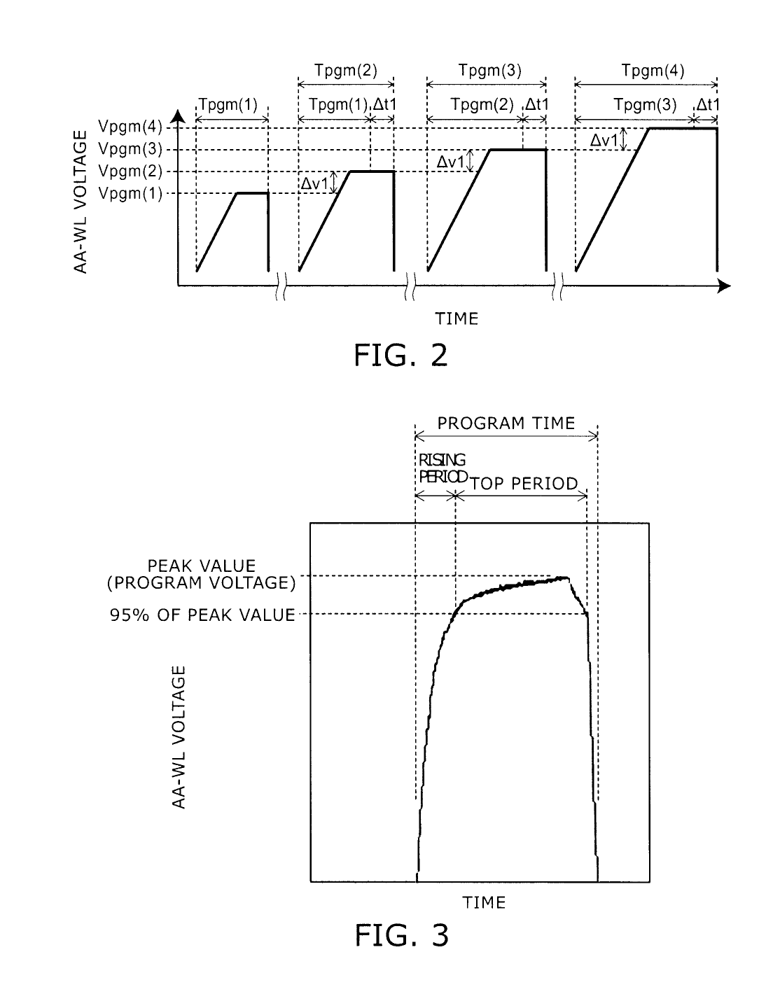

FIG. 2 is a chart diagram illustrating a programming operation of the nonvolatile memory device according to the embodiment in which a horizontal axis indicates time and a vertical axis indicates voltage;

FIG. 3 is a chart diagram showing a specific example of a profile of one pulse of an AA-WL voltage in which a horizontal axis indicates time and a vertical axis indicates program voltage; and

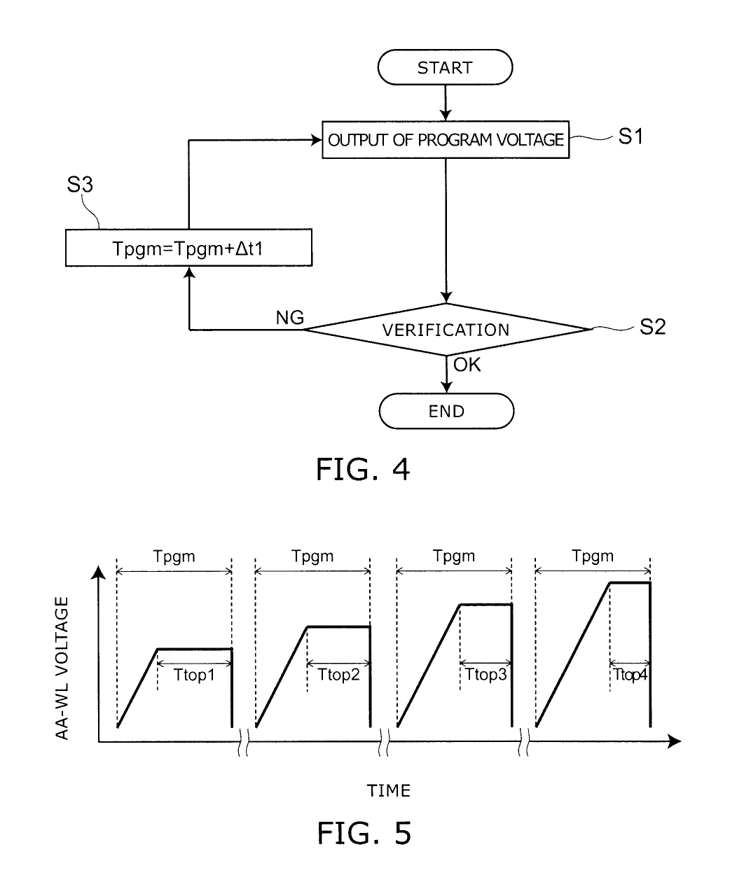

FIG. 4 is a chart diagram illustrating an operation of the nonvolatile memory device according the embodiment.

A nonvolatile memory device according to the embodiment is an EEPROM (Electrically Erasable Programmable Read-Only Memory), which is, for example, a NAND flash memory formed on a silicon substrate.

As shown in FIG. 1, in a nonvolatile memory device 1 according to the embodiment, a cell well is formed in an upper layer portion of the silicon substrate, and a memory array 11 is provided in this cell well. In the memory cell array 11, a plurality of bit lines BL extending in one direction (hereinafter referred to as “bit line direction”) and a plurality of word lines WL extending in another direction (hereinafter referred to as “word line direction”) are provided. Both the bit line direction and the word line direction are parallel to the upper face of the silicon substrate, and are orthogonal to each other. The plurality of word lines, for example, 64 word lines, constitute one group, and a pair of selective gate lines SG is provided on both sides of the group. In contrast, in an area directly below a bit line BL in the upper layer portion of the cell well, an active area which is mutually separated by an STI (shallow trench isolation) is formed.

A floating electrode is provided between the active area and the word line WL. As a result, a memory cell MC including one floating electrode is formed at each closest point of the active area and the word line WL. Further, a selective transistor ST is formed at each closest point of the active area and the selection gate line SG. In addition, one NAND string NS is constituted by the 64 memory cells MC that share one active area in common and the two selective transistors ST on the both sides of these memory cells MC. In other word, the NAND string includes a plurality of the memory cells connected in series. One block BLK is constituted by a plurality of NAND strings NS arranged in the word line direction. Moreover, a source line SL that extends in the word line direction is provided for each block. In the memory cell array 11, a plurality of blocks BLK, for example, 1024 blocks BLK are provided in the bit line direction. Moreover, in each block, one end of each NAND string NS is connected to each bit line BL, while the other end is connected to a common source line SL.

When viewed from the memory cell array 11, a sense amplifier circuit 12 is provided in the bit line direction. In the sense amplifier circuit 12, sense amplifiers SA are provided in the same number as the bit lines BL, and each of these sense amplifiers SA is connected to the corresponding bit lines BL. The sense amplifier SA measures or applies a potential of each bit line BL. Moreover, when viewed from the memory array 11, a row decoder 13 is provided in the word line direction. To the row decoder 13, the word lines WL and the selective gate lines SG are connected. The row decoder 13 selects these lines to supply voltage.

Furthermore, the nonvolatile memory device 1 is provided with a controller 14. The controller 14 inputs signals such as a program enable signal WEn, a read enable signal REn, an address latch enable signal ALE, and a command latch enable signal CLE, and the like from a Host or a Memory controller HM, and controls overall operations of the nonvolatile memory device 1. Specifically, the controller 14 controls operations of programming, reading, erasing of data, and the like.

Furthermore, a data input/output buffer 15, a ROM fuse 16, and a voltage generation circuit 17 are also provided in the nonvolatile memory device 1. The data input/output buffer 15 receives and sends data between the sense amplifier SA and an external input/output terminal, and receives command data and address data. The ROM fuse 16 stores therein fixed data. The controller 14 reads out this fixed data as necessary.

A pulse generation circuit PG and a plurality of charge pumps CP are provided in the voltage generation circuit 17. The charge pump CP is a circuit for generating a voltage and the generated voltage is output to the pulse generation circuit PG. The pulse generation circuit PG is a circuit for outputting a voltage input from the charge pumps CP after being shaped in pulses. In addition, an output voltage of the voltage generation circuit 17 is input to the row decoder 13. A drive circuit 20 is including the row decoder 13, the controller 14, the ROM fuse 16, and the voltage generation circuit 17.

Next, an operation of the nonvolatile memory device 1 according to the embodiment will be explained.

A feature of the embodiment lies in the programming operation of data, and thus descriptions will be given mainly on the programming operation.

As shown in FIG. 1, when a signal including program data is input from the Host or the Memory controller HM, this signal is input to the controller 14 through the data input/output buffer 15. The controller 14 outputs a control signal to the voltage generation circuit 17, to switch the charge pump CP to be driven, to generate a program voltage, pass voltage, and selective gate voltage. In the meantime, the controller 14 controls the pulse generation circuit PG to output these voltages at timings. Furthermore, the controller 14 outputs a control signal also to the low decoder 13 so as to output a program voltage to a selected word line WL, which passes the memory cell MC to which data is to be stored, among the plurality of word lines WL belonging to each block BLK, while the controller 14 outputs a pass voltage to non-selected word lines WL, to thereby make the selective gate line SG output the selective gate voltage. The controller 14 may output a voltage other than Vass to one of the non-selected word lines WL (e, q, cutoff voltage VISO which turn off the memory cell MC to which data is to be stored).

In contrast, the controller 14 outputs a control signal to the sense amplifier circuit 12, to drive each sense amplifier SA. Specifically, the controller 14 controls the sense amplifier SA connected to the memory cell in which data is to be programmed, to output a potential, for example, a ground potential, which puts the selective transistor ST on the bit line side in the on-state, while the controller 14 controls the sense amplifiers SA connected to the memory cells in which data is not to be programmed, to output a potential higher than the potential, for example, the ground potential which puts the selective transistor ST on the bit line side in the off-state.

As a result, in the memory cell MC subjected to the programming, the program voltage is applied between the active area and the word line WL, while in other memory cells MC, the pass voltage or cutoff voltage VSIO is applied between the active area and the word line WL. As a result, in other memory cells, the active area becomes a conductive state, while in the memory cell subjected to the programming, electrons are injected from the active area to the charge accumulation layer. As a result, a threshold value of the transistor that constitutes the memory cell MC changes. As described, in the memory cell MC, data is programmed each time the program voltage is applied. In contrast, by detecting the threshold value of the memory cell, data programmed in this memory cell is read out. Furthermore, via the word lines from the row decoder, the data is erased by applying an erase voltage to all the memory cells belonging to each block to discharge electrons from the charge accumulation layer towards the active area.

Hereinafter, in the specification, a voltage between the active area and the word line is referred to as “AA-WL voltage”. The AA-WL voltage is a potential of the word line WL with a standard of 0 V, which is, for example, a voltage measured by bringing a probe needle into contact with the word line WL. The AA-WL voltage may be measured also by simply monitoring a voltage of an output portion of the charge pump.

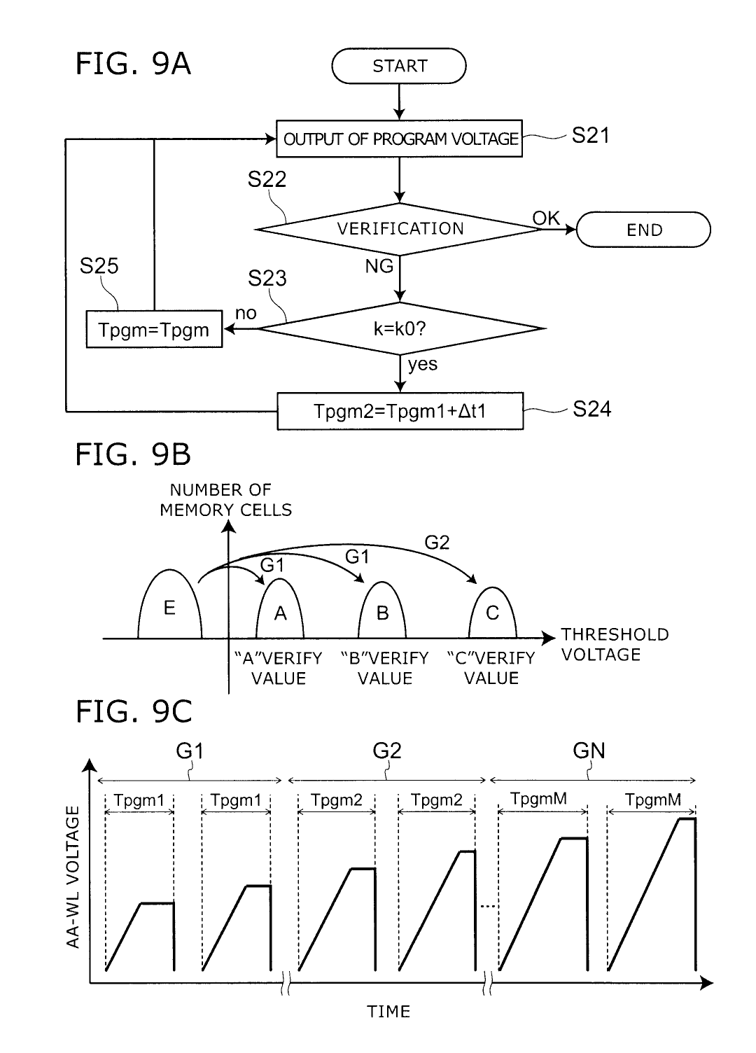

As shown in FIG. 2, in the embodiment, a program voltage is output in pulses from the row decoder 13 to the word line WL. Then, after the program voltage is output, data is read out from each memory cell, and it is verified whether or not the data has been normally programmed in each memory cell by collating the data with the data stored in the controller 14 or latch circuit in sense amplifier SA. Then, a program voltage is output again with respect to an insufficiently programmed memory cell, i.e., the memory cell whose threshold value has not reached a verify value (FIG. 9B). At this time, a program voltage to be output at each timing in pulses is increased by a predetermined voltage Δv1 with respect to the program voltage used in the programming operation performed last time. Furthermore, a time in which each output of a program voltage is continued (hereinafter referred to as “program time”) is increased each by a time Δt1.

That is, in the case of repeating the output of the program voltage and the verification of the memory cell n times (n is an integer not less than 3), when a program voltage in the k-th output (k is an integer not less than 2 and not less than n) is set to Vpgm(k), a constant voltage is set as Δv1, a time in which the k-th output is continued (program time) is set to Tpgm(k), and a constant time is set as Δt1. the following formulae (1) and (2) is set to be satisfied in continuously outputting the program voltage not less than three times:

Vpgm(k)=Vpgm(k−1)+Δv1 (1)

Tpgm(k)=Tpgm(k−1)+Δt1 (2).

The program time includes both a “rising period” in which the voltage between the active area and the word line (AA-WL voltage) increases from zero to almost the program voltage, and a “top period” in which the AA-WL voltage is maintained approximately at the program voltage. Hereafter, for convenience sake, one cycle during which the AA-WL voltage decreases to zero after the AA-WL voltage has increased from zero to the program voltage may be referred to as “pulse”.

As shown in FIG. 3, actually, the AA-WL voltage continuously changes in many cases. In this case, for each pulse of the AA-WL voltage, a peak value of the AA-WL voltage is set to a program voltage, a period of time from the point where the AA-WL voltage is zero to the point where the AA-WL voltage has reached 95% of the peak value is defined to be “rising period”, and a period of time in which the AA-WL voltage is not less than 95% of the peak value is defined to be “top period”.

The operation shown in FIG. 2 can be realized by the procedure shown in FIG. 4. That is, a program voltage is output as shown in step S1 of FIG. 4. After that, a verification of the memory cell is performed as shown in step S2. Then, if there is any memory cell in which data has not been programmed properly (threshold value of the memory cell has not reached the verify value), a status of the memory cell is determined to be “NG”, and the sequence proceeds to step S3. In step S3, a constant time Δt1 is added to the program time Tpgm. That is, the processing indicated by the formula (2) is performed. Then, the sequence returns to step S1. The program voltage is outputs to the memory cell whose status is “NG”. In contrast, if data has been properly programmed in all the memory cells, the status of the memory cell is determined to be “OK” in step S2, and the programming operation is terminated.

Next, the effect of the embodiment will be explained.

In the embodiment, in the case where the program voltage is output in pulses a plurality of times, the program voltage increases only by a constant voltage Δv1 from the last program voltage. As a result, it is possible to effectively program data in the memory cell in which data has not been sufficiently programmed in the output of the program voltage last time.

Moreover, in the rising period, in the case where the AA-WL voltage increases in proportion to time, the rising period becomes longer in proportion to an increase in the program voltage. Therefore, in the embodiment, an overall program time is increased only by the constant time Δt1 from the program time in the last time. As a result, it is possible to ensure a satisfactory length of the rising period irrespectively of a value of the program voltage, and to keep the length of the top period constant. As shown in FIG. 3, the profile of an actual AA-WL voltage is not completely linear, but is curved in many cases. In such cases, however, since the profile in the rising period can be approximated by a straight line to a certain extent, it is possible to keep the length of the top period approximately constant. As a result, in the initial stage of the pulse having a relatively low voltage, it is possible to prevent the top period from becoming too long, thereby realizing an overall high speed programming operation. That is, it is possible to make the top period constant between the pulse in the initial stage having a relatively low voltage and the pulse in the final stage having a relatively high voltage.

Furthermore, in the embodiment, even in the case where a transition period from the rising period to the top period cannot be detected directly for each pulse of the AA-WL voltage, it is still possible to keep the top period constant by controlling an overall program time.

Next, a comparative example of the embodiment will be explained.

FIG. 5 is a chart diagram illustrating a programming operation of a nonvolatile memory device according to the comparative example, in which a horizontal axis indicates time and a vertical axis indicates voltage.

As shown in FIG. 5, in the comparative example, a program voltage is increased for each pulse of the AA-WL voltage. In contrast, the program time Tpgm is set constant among pulses.

Also in the comparative example, an increase rate of the AA-WL voltage over time in the rising period is approximately constant. Therefore, the higher the program voltage is, the longer the rising period is, and because of this, the top period becomes shorter. That is, as shown in FIG. 5, the relationship of Ttop1>Ttop2>Ttop3>Ttop4 holds. Therefore, when the program time Tpgm is set such that a required minimum top period is ensured for the pulse in the initial stage having a relatively low program voltage, in the pulse having the highest program voltage, the AA-WL voltage cannot reach 95% of the peak value within the program time Tpgm. In contrast, when the program time Tpgm is set such that the top period is ensured even for the pulse having the highest program voltage, the top period becomes too long for the pulse in the initial stage having a relatively low program voltage, thereby in turn making an overall program time too long.

In contrast, in the present embodiment, it is possible to realize a constant top period between the pulse in the initial stage having a relatively low program voltage and the pulse in the final stage having a relatively high program time. As a result, it is possible to reach the top period within the program period Tpgm for the pulse having the highest program voltage, while preventing the top period from becoming too long for the pulse in the initial stage having a relatively low program voltage, thereby being able to realize an overall high speed programming operation.

Next, a modified example of the embodiment will be explained.

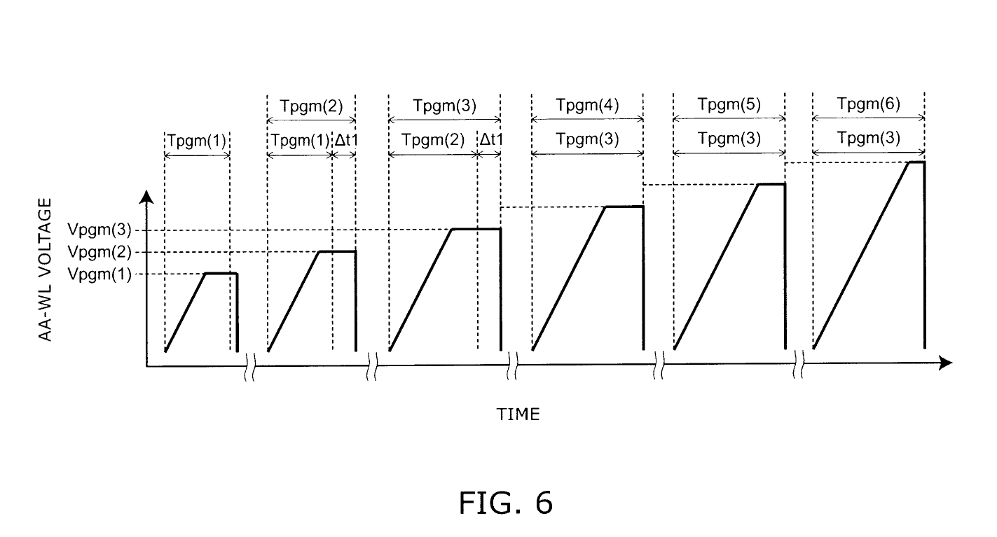

FIG. 6 is a chart diagram illustrating a programming operation of a nonvolatile memory device according to the modified example, in which a horizontal axis indicates time and a vertical axis indicates voltage; and

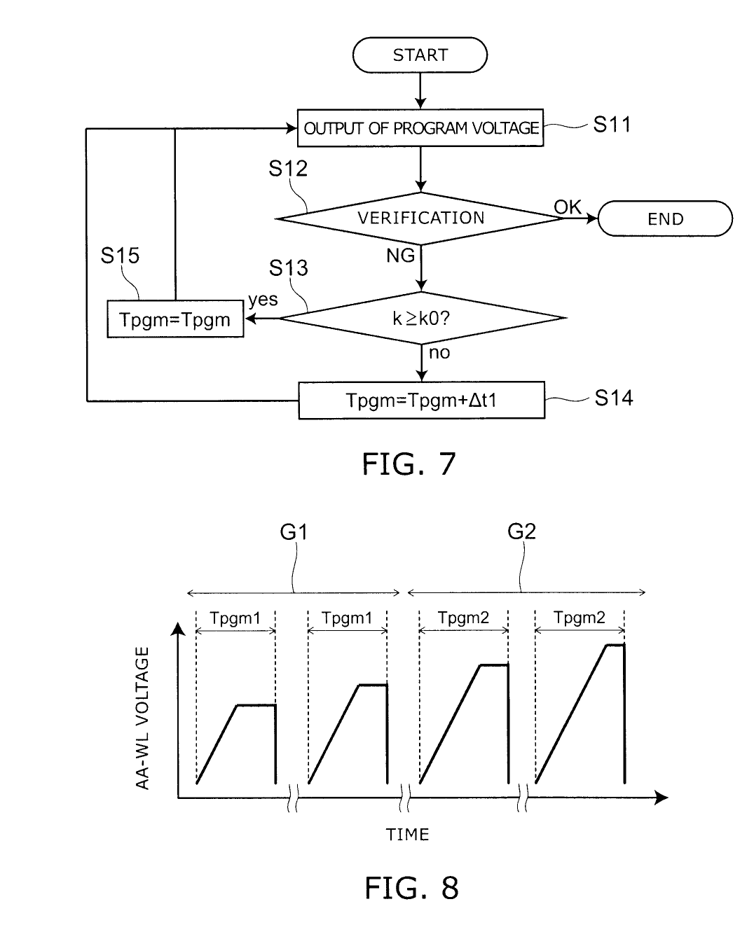

FIG. 7 is a flowchart illustrating an operation of the nonvolatile memory device according to the modified example.

As shown in FIG. 6, in the modified example, by the time the pulse of the program voltage reaches a number of times (value k0), the later the pulse is to be output, the longer the program time is set like in the case of the above-described first embodiment. Then, after the pulse of the program voltage reaches the number of times (value k0), the program time is set constant. Incidentally, the later the pulse is to be output, the higher the program voltage is set throughout the programming operation.

That is, in the case of repeating the output of the program voltage and the verification of the memory cell n times, for the continuous outputs not less than three, for example, for the first to the third outputs, the above formulae (1) and (2) are set so as to be satisfied. Then, for the subsequent continuous outputs not less than two, for example, for the fourth to the sixth outputs, the following formulae (3) and (4) are set so as to be satisfied.

Vpgm(k)>Vpgm(k−1) (3)

Tpgm(k)=Tpgm(k−1) (4)

The operation shown in FIG. 6 can be realized by the procedure shown in FIG. 7. That is, a program voltage is output as shown in step S11 of FIG. 7, and then a verification of the memory cell is performed as shown in step S12. After that, if there is any memory cell in which data has not been programmed properly, the status of the memory cell is determined to be “NG”, and the sequence proceeds to step S13. In step S13, the memory cell is determined whether or not the number of outputs of the program voltage is not less than a value k0. If the number of outputs k is less than value k0, the sequence proceeds to step S14, and the constant time Δt1 is added to the program time Tpgm. That is, the process indicated by the formula (2) is performed. Then, the sequence returns to step S11. The program voltage is outputs to the memory cell whose status is “NG”. Incidentally, in the example shown in FIG. 6, the value k0 is 4. Furthermore, in step S13, if the number of outputs is not less than the value k0, the sequence proceeds to step S15 where the program time Tpgm is set constant. That is, the process indicated by the formula (4) is performed. After that, the sequence returns to step S11. In contrast, if the data has been properly programmed in all the memory cells, the status of the memory cell is determined to be “OK” in step S12, and the programming operation is terminated.

According to the modified example, for the pulses to be output in the first half of the programming operation, the program time is set longer step by step as the number of outputs becomes larger, while for the pulses to be output in the latter half of the programming operation, the program time is set constant among the pulses. Since the program voltage is relatively high for the pulses to be output in the latter half of the programming operation, there may be a case where electrons are injected into the charge accumulation layer sufficiently in the first half of the top period. In such a case, the latter half of the top period results in a useless time. Therefore, in the first half in which the programming operation is performed with a low program voltage Vpgm, the program time is adjusted so that the top period becomes constant depending on the program voltage, while in the latter half of the programming operation having a high program voltage Vpgm, the program time is set constant, thereby making the top period substantially shorter. As a result, while reducing each program time, the number of outputs itself of the program voltage is reduced, thereby being able to realize an overall higher speed program operation.

The configuration, the operation, and the effect of the modified example are the same as the configuration, the operation, and the effect of the above-described first embodiment, except for what has been just described above. Variations of the first embodiment are not limited to the modified example, and as long as the above formulae (1) and (2) are satisfied for outputs not less than three, performed continuously, of the program voltage, the same effect can be obtained. Furthermore, in the modified example, the number of outputs in which the waveform of the program voltage is changed is set to three. However, the number of outputs is not limited to this.

Next, a second embodiment will be explained.

FIG. 8 is a chart diagram illustrating a programming operation of a nonvolatile memory device according to the embodiment, in which a horizontal axis indicates time and a vertical axis indicates voltage; and

FIG. 9A is a flowchart illustrating an operation of the nonvolatile memory device according to the embodiment.

FIG. 9B is a graph illustrating programming operation of the nonvolatile memory device according to the embodiment, in which a horizontal axis indicates threshold voltage and a vertical axis indicates number of memory cells.

FIG. 9C is a chart diagram illustrating a programming operation of the nonvolatile memory device according to the embodiment, in which a horizontal axis indicates time and a vertical axis indicates voltage.

As shown in FIG. 8, in the embodiment, the output of the program voltage and the verification of the memory cell are repeated a plurality of times like in the case of the above-described first embodiment. Further, the later the pulse of the AA-WL voltage is to be output, the higher the program voltage is set.

In contrast, the embodiment differs from the above-described first embodiment in that the pulses of the AA-WL voltage to be output a plurality of times are divided into a plurality of groups along the time axis in such a manner that the later the group the pulse belongs to, the longer the program time is set, while the program time is mutually equal among the pulses belonging to the same group. In the example shown in FIG. 8, the pulses are divided into two groups. The program time for each of the pulses which belong to the first half group G1 is Tpgm1, and the program time for each of the pulses which belong to the latter half group G2 is Tpgm2, where the program time Tpgm2 is longer than the program time Tpgm1.

The operation shown in FIG. 8 can be realized by the procedure shown in FIGS. 9A to 9C. That is, the program voltage is output as shown in S21 of FIGS. 9A to 9C. For the output in the first time, the program time is set to Tpgm1. After that, as shown in step S22, the verification of the memory cell is performed. Then, if there is any memory cell in which data has not been programmed properly, the status of the memory cell is determined to be “NG”, and the sequence proceeds to step S23. In step S23, it is determined whether or not the number of outputs k of the program voltage is a value k0. If the number of outputs k is k0, the sequence proceeds to step S24, and a constant time Δt1 is added to the program time Tpgm1. As a result, the program time is changed from Tpgm1 to Tpgm2. Then, the sequence returns to step S21. In step S23, if the number of outputs k is not the value k0, the sequence proceeds to step S25, and the program time Tpgm is set constant. Then, the sequence returns to step S21. In contrast, if data has been properly programmed in all the memory cells, the status of the memory cell is determined to be “OK” in step S22, and the programming operation is terminated.

According to the embodiment, for the pulses to be output in the first half (G1) of the programming operation, the program time is set relatively short, while for the pulses to be output in the latter half (G2) of the programming operation, the program time is set relatively long. Furthermore, the programming time is set constant within each group. In contrast, irrespectively of the first half and the latter half of the programming operation, the program voltage is increased step by step in the initial stage. As a result, in the first half (G1) of the programming operation, the later the pulse is to be output, the shorter the top period becomes. In the same way, in the latter half (G2) of the programming operation, the later the pulse is to be output, the shorter the top period becomes.

For example, the case is considered where the memory cells store values in four levels (level “A”, level “B”, level “C” in FIG. 9B), and the lowest value (level “E” in FIG. 9B) has been programmed in each memory cell in the initial stage, and values in two levels are to be programmed in the memory cell. That is, supposing that levels that can be stored in each memory are set to a first level (level “E”), a second level (level “A”), third level (level “B”), and a fourth level (level “C”) in ascending order of threshold voltage of the memory cell, both the case where a value in each memory cell is to be changed from the first level to the second level and third level the case where a value in each memory cell is to be changed from the first level to the fourth level are to be considered. In this case, by setting the reference value (k0) to the number of pulses for programming the second and third levels, it is possible to perform an appropriate programming operation for each value. More specifically, the programming of the second and third values are performed in the first half (G1) of the programming operation, and the programming of the fourth value is performed in the latter half (G2) of the programming operation. In this case, the reference value (k0) is set between the pulse for programming the third value and the pulse for programming the fourth value. As a result, it is possible to appropriately set the program time for each threshold value distribution corresponding to each value, thereby realizing a high speed programming operation.

The configuration, the operation, and the effect of the embodiment are the same as the configuration, the operation, and the effect of the above-described first embodiment, except for what has been just described above. In the embodiment, description has been given with respect to the case where the pulses to be output a plurality of times in the programming operation are divided into two groups (see FIG. 9C). However, the embodiment is not limited to this example, and they may be divided into three or more groups (e.g. “N” groups case in FIG. 9C). The foregoing operation can be realized, for example, by providing a plurality of stages for the procedure shown in step S23 in FIG. 9 through the use of different reference values (k0).

Next, a modified example of the embodiment will be explained.

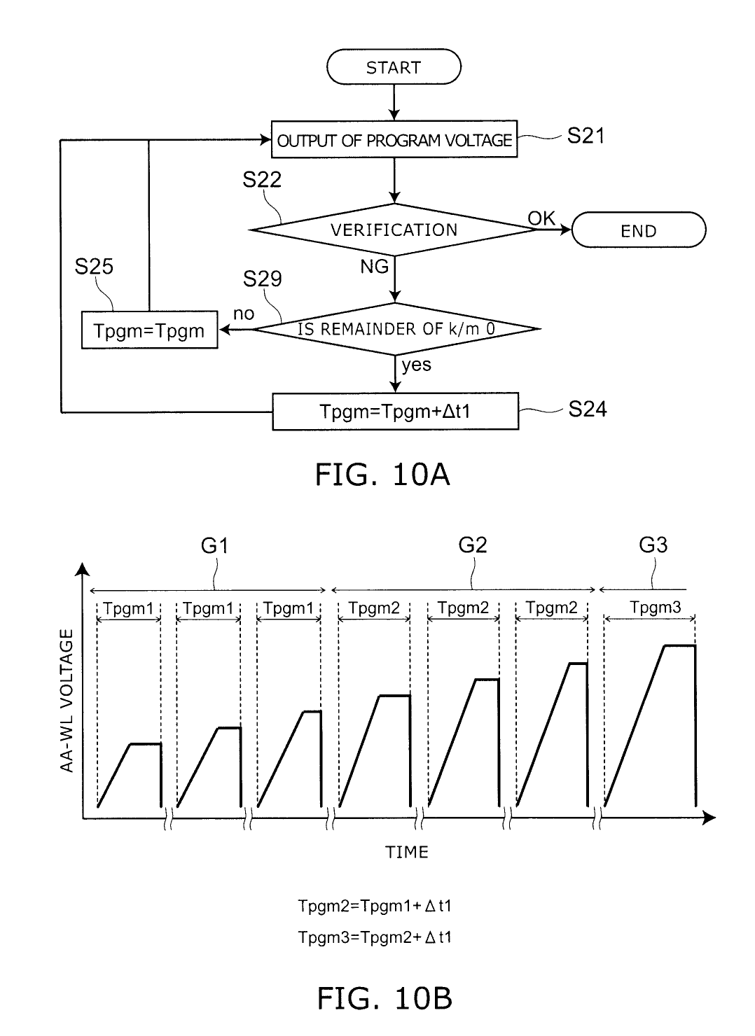

FIG. 10A is a flowchart diagram illustrating an operation of the nonvolatile memory device according to the modified example.

FIG. 10B is a chart diagram illustrating a programming operation of a nonvolatile memory device according to t modified example of the embodiment.

A profile of the AA-WL voltage in the modified example is the same as the profile shown in FIG. 8. However, in the modified example, as compared with the above-described second embodiment (see FIG. 9A), the flowchart for realizing this profile is different.

In the modified example, the pulses of the program voltage are grouped, each being made up of m pulses (m is an integer not less than one). In this case, the step S29 shown in FIG. 10 is executed in replace of the step S23 shown in FIG. 9A. In step S29, it is determined whether or not a remainder after dividing the number of output k of the program voltage by m is 0 (zero). For example, supposing that m is 3, then if the number of output k is a multiple of 3, such as 3, 6, 9, . . . , the remainder after dividing k by m is 0. Therefore, the sequence proceeds to step S24, and the program time Tpgm is extended. In other cases, the sequence proceeds to step S25, and the program time Tpgm is maintained as it is. Also in this manner, it is possible to realize the operation of the above-described second embodiment. The configuration, the operation, and the effect of the modified example are the same as the configuration, the operation, and the effect of the above-described second embodiment, except for what has been just described above.

Next, a third embodiment will be explained.

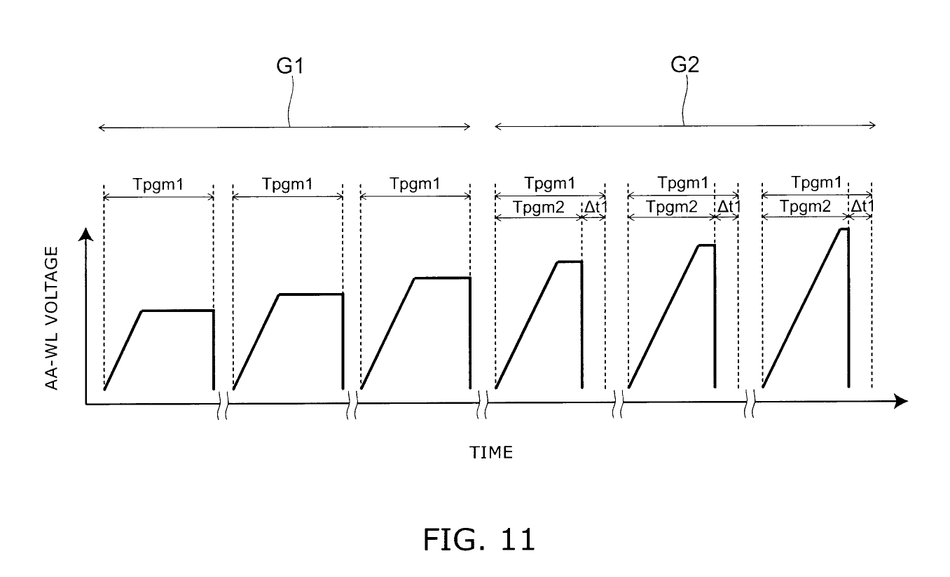

FIG. 11 is a chart diagram illustrating a programming operation of a nonvolatile memory device according to the embodiment, in which a horizontal axis indicates time and a vertical axis indicates voltage.

As shown in FIG. 11, the embodiment differs from the above-described second embodiment (see FIG. 8) in that the program time Tpgm2 for each of the pulses belonging to the latter half group G2 is shorter than the program time Tpgm1 for each of the pulses belonging to the first half group G1. Such operation can be realized by setting the constant time Δt1 to a negative value in step S24 shown in FIG. 9 or 10.

Since the program voltage is relatively high in the latter half (group G2) of the programming operation, electrons may be sufficiently injected into the floating electrode in the first half of the top period. In such case, the latter half of the top period results in a useless time. In the embodiment, by making the top period for each pulse shorter in the latter half (group G2) of the programming operation, it is possible to omit such a useless time. As a result, it is possible to realize a higher speed programming operation, while securing the injection of electrons. The configuration and the operation of the embodiment are the same as the configuration, and the operation of the above-described second embodiment, except for what has been just described above. In the embodiment, the pulses may be divided into not less than three groups like in the case of the second embodiment. Moreover, the embodiment may be combined with the above-described modified example of the second embodiment.

Next, a fourth embodiment will be explained.

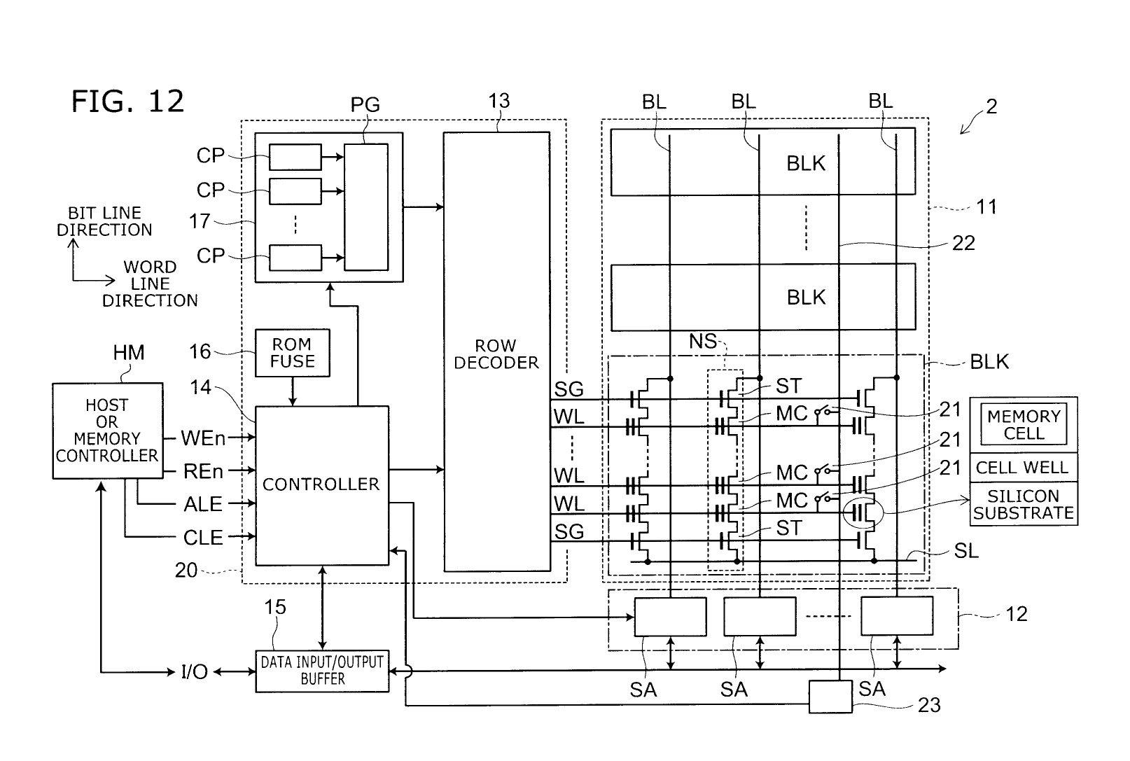

FIG. 12 is a block diagram illustrating a nonvolatile memory device according to the embodiment; and

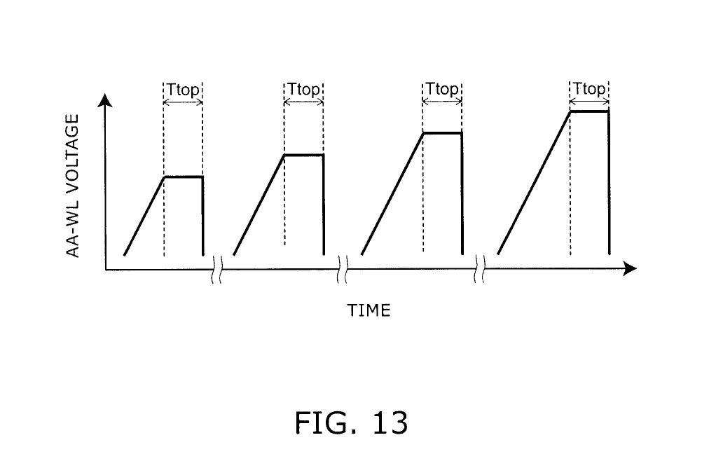

FIG. 13 is a chart diagram illustrating a programming operation of the nonvolatile memory device according to the embodiment, in which a horizontal axis indicates time and a vertical axis indicates voltage.

As shown in FIG. 12, a nonvolatile memory device 2 according to the embodiment is provided with switches 21, a potential detection wiring 22 and a potential measuring circuit 23 in addition to the configuration of the nonvolatile memory device 1 (see FIG. 1) according to the above-described first embodiment. The switches 21 are provided by the same number as the number of the word lines WL, and one end of each switch 21 is connected to the corresponding word line WL. An operation of the respective switches 21 is controlled by the controller 14. For example, one potential detection wiring 22 is provided, and extends in the bit line direction over all the blocks BLK. To the potential detection wiring 22, the other end of the respective switches 21 is connected. Furthermore, one end of the potential detection wiring 22 is connected to the potential measuring circuit 23. The potential measuring circuit 23 measures the potential of the potential detection wiring 22, and outputs a measurement result to the controller 14.

Next, an operation of the nonvolatile memory device 2 according to the embodiment will be explained.

In the embodiment, prior to the programming operation, a profile of the AA-WL voltage as shown in FIG. 3, i.e., a change in potential of the word line WL when outputting the program voltage to the word line WL is measured, and a value corresponding to 95% of the peak value is calculated. This calculation may be performed with respect to a prototype of the nonvolatile memory device 2, and the result of calculation may be stored, for example, in the POM fuse 16 of each product, or may be performed at the time of shipping each product from the factory or every time a programming operation is performed in each product.

When performing a programming operation of data, as shown in FIG. 12, the controller 14 puts the switch 21 connected to the word line WL to which the program voltage is output, in the on-state, while putting the rest of the switches 21 in the off-state, to thereby connect the word line WL to which the program voltage is output, to the potential detection wiring 22. Then, the potential measuring circuit 23 measures a potential of the potential detection wiring 22, and outputs the measurement result to the controller 14. As a result, the controller 14 detects a voltage (AA-WL voltage) between the word line WL to which the programming voltage is output and the active area. Furthermore, when the AA-WL voltage has reached a value corresponding to 95% of the above-described peak value, it is determined that the AA-WL voltage is shifted from the rising period to the top period as shown in FIG. 3. After an elapse of a time (e, q, Ttop) from this point, the output of the program voltage is stopped. As a result, as shown in FIG. 13, the top period Ttop can be set constant among pulses. Like in the case of the above-described first embodiment, the later the pulse is to be output, the higher the program voltage is set. Accordingly, the later the pulse is to be output, the longer the rising period becomes. Therefore, the later the pulse is to be output, the longer the program time for each pulse becomes.

According to the embodiment, since the AA-WL voltage can be measured directly, it is possible to adjust the top period based on an actual profile of the AA-WL voltage. As a result, it is possible to make the top period uniform with a higher degree of accuracy, thereby realizing a higher speed programming operation more efficiently. The configuration, the operation, and the effect of the embodiment are the same as the configuration, the operation, and the effect of the above-described first embodiment, except for what has been just described above. In the embodiment, following the above-described first embodiment, the point of time at which the AA-WL voltage has reached 95% of the peak value is defined to be a transition time between the rising period and the top period. However, the embodiment is not limited to this.

Next, a modified example of the embodiment will be explained.

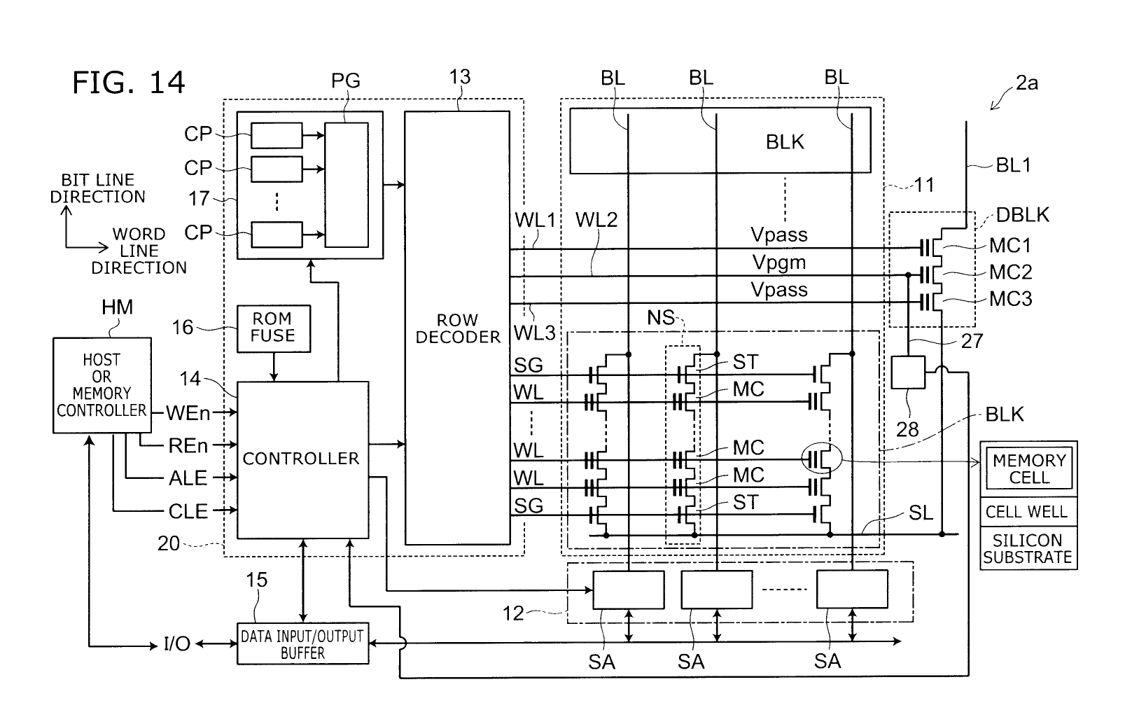

FIG. 14 is a block diagram illustrating a nonvolatile memory device according to the modified example.

A profile of the AA-WL voltage in the modified example is the same as the profile shown in FIG. 13.

As shown in FIG. 14, a nonvolatile memory device 2a according to the modified example is further provided with one bit line BL1, three memory cells MC1 to MC3, three word lines WL1 to WL3, one potential detection wiring 27 and one potential measuring circuit 28 in addition to the configuration of the nonvolatile memory device 1 (see FIG. 1) according to the above-described first embodiment. The memory cells MC1 to MC3 share one active area in common, and are mutually connected in series between the bit line BL1 and the source line SL. The memory cells MC1 to MC3 are included a dummy block DMLK. One end of each of the word lines WL1 to WL3 is connected to an output terminal of the row decoder 13, and the other end is connected to each of the gate electrodes of the memory cells MC1 to MC3. The potential detection wiring 27 is connected between the word line WL2 and the potential measuring circuit 28. The potential measuring circuit 28 measures a potential of the potential detection wiring 27, and outputs the measurement result to the controller 14.

Next, an operation of the nonvolatile memory device 2a according to the modified example will be explained.

In the modified example also, prior to the programming operation, the profile of the AA-WL voltage as shown in FIG. 3 is obtained, and a value corresponding to 95% of the peak value is calculated.

Furthermore, as shown in FIG. 14, in order to program data in the memory cell MC, the row decoder 13 outputs the program voltage to any of the plurality of word lines WL, while outputting the pass voltage Vpass to other word lines WL belonging to the same block. At this time, the low decoder 13 outputs the program voltage Vpgm to the word line WL2 while outputting the pass voltage Vpass to the word line WL1 and the word line WL3. A potential of the word line WL2 is input to the potential measuring circuit 28 via the potential detection wiring 27. Then, the potential measuring circuit 28 measures this potential, and outputs the measurement result to the controller 14. Moreover, when the potential of the word line WL2 has reached the value corresponding to 95% of the above-described peak value, the controller 14 determines that the AA-WL voltage applied to the memory cell subjected to the programming has shifted from the rising period to the top period as shown in FIG. 3. Then, after an elapse of a time (e, q, Ttop) from this point, the output of the program voltage to the word lines WL and WL2 is stopped. As a result, as shown in FIG. 13, the top period Ttop can be set constant among the respective pulses.

According to the modified example, by measuring the AA-WL voltage with respect to a dummy memory cell MC2 provided in a dummy block DBLK, it is possible to estimate an AA-WL voltage of the memory cell MC subjected to the programming without affecting the AA-WL voltage of the memory cell MC subjected to the programming, and to determine the timing at which the AA-WL voltage is shifted from the rising period to the top period. As a result, like in the case of the above-described fourth embodiment, it is possible to make the length of the top period constant among the pulses.

Furthermore, in the modified example, the dummy memory cells MC1 and MC3 are provided on both sides of the dummy memory cell MC2, and the program voltage Vpgm is applied to the memory cell MC2, and the pass voltage Vpass is applied to the memory cells MC1 and MC3. In this manner, it is possible to approximate the environment of the memory cell MC2, for example, a surrounding electric field distribution, to the environment of the memory cell MC in which data is actually to be programmed. As a result, the AA-WL voltage to be applied to the memory cell MC can be estimated with a higher degree of accuracy.

The configuration, the operation, and the effect of the modified example are the same as the configuration, the operation, and the effect of the above-described fourth embodiment, except for what has been just described above.

Next, a fifth embodiment will be explained.

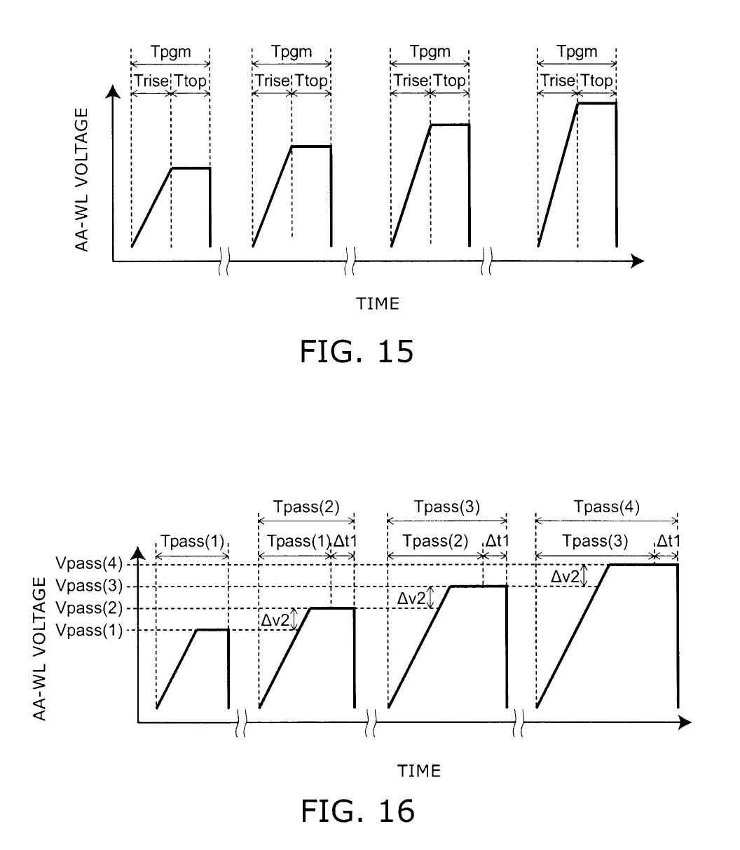

FIG. 15 is a chart diagram illustrating a programming operation of a nonvolatile memory device according to the embodiment, in which a horizontal axis indicates time and a vertical axis indicates voltage.

As shown in FIG. 15, in the embodiment, like in the case of the above-described fourth embodiment, the top period Ttop is set constant among the pulses, and the length of the rising period Trise is also set as constant as possible by controlling a rate of increase of the AA-WL voltage. For example, the controller 14 makes a rise in the AA-WL voltage steeper such that the higher the program voltage of the pulse is, the more the number of the charge pumps CP to be driven is increased. As a result, among all the pulses, the length of the rising period Trise becomes approximately constant, thereby making the length of the program time Tpgm approximately constant.

According to the embodiment, by making the length of the rising period constant among the pulses, it is possible to still more reduce the time required for the programming operation. The configuration, the operation and the effect of the embodiment are the same as the configuration, the operation, and the effect of the above-described fourth embodiment, except for what has been just described above. In the embodiment, the configuration of the nonvolatile memory device may be the same as the configuration of the modified example of the above-described fourth embodiment.

Next, a sixth embodiment will be explained.

FIG. 16 is a chart diagram illustrating a programming operation of a nonvolatile memory device according to the embodiment, in which a horizontal axis indicates time and a vertical axis indicates voltage.

As shown in FIG.16, in the embodiment, the pass voltage Vpass is output in such a manner that the later the pulse is to be output, the higher the pass voltage is set, and the longer the time in which the output of the pass voltage is continued is set (hereinafter referred to as “pass time”). More specifically, when performing a programming operation, among the plurality of memory cells MC that constitute one NAND string, by applying a program voltage that makes electrons be injected into the floating electrode is applied to one memory cell MC (hereinafter referred to as “selected memory cell”) via the word line WL, while by applying a pass voltage that puts the active area in the conductive state (hereinafter referred to as a “non-selected memory cell”) to the rest of the memory cells MC via the word lines WL, the output of these voltages and the verification of the memory cell is repeated. The word line to be connected to the selected memory cell is referred to as “selected word line WLs”, and the word line to be connected to the non-selected memory cell is referred to as a “non-selected word line WLns”. Then, the following formulae (5) and (6) is set to be satisfied in continuously outputting the pass voltage not less than three times, when a pass voltage in the k-th output is set to Vpass(k), a pass time is set to Tpass(k), and a constant voltage is set to Δv2.

Vpass(k)=Vpass(k−1)+Δv2 (5)

Tpass(k)=Tpass(k−1)+Δt1 (6)

According to the embodiment, by controlling the pass time depending on the pass voltage, it is possible to prevent the top period of the pass voltage from becoming too long, thereby realizing an efficient programming operation. The configuration of the embodiment is the same as the configuration of the above-described first embodiment, except for what has been just described above.

In the embodiment, the example in which the pass voltage Vpass and the pass time Tpass are set in accordance with the above formulae (5) and (6) has been shown. However, the embodiment is not limited to this. When repeating the output of the pass voltage, it is only necessary to satisfy such condition that the later the pulse is to be output, the higher the pass voltage is set and the longer the pass time is set.

Next, a seventh embodiment will be explained.

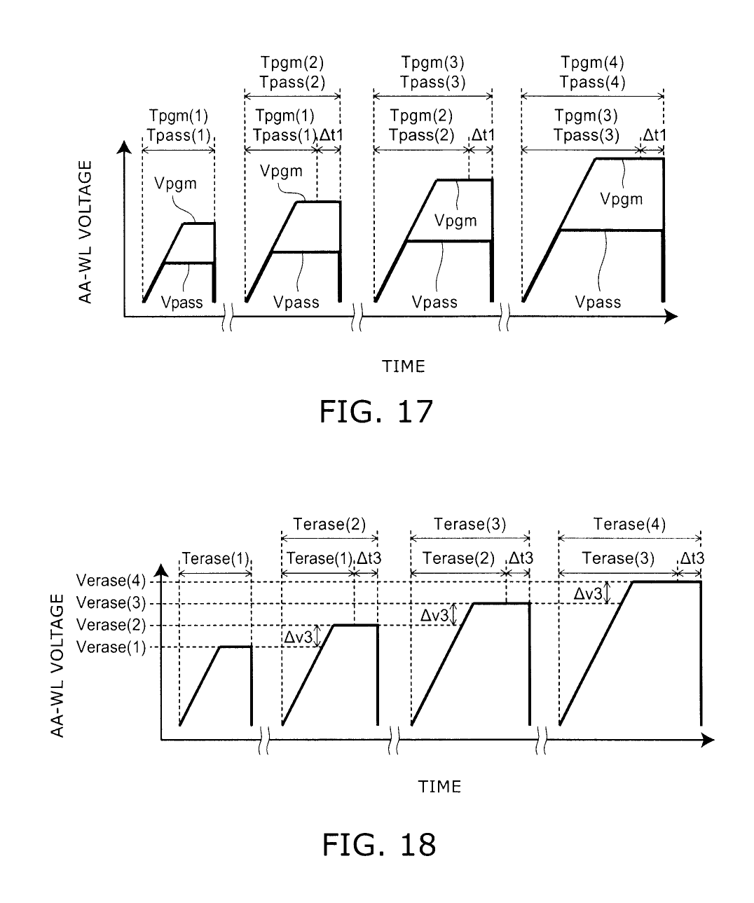

FIG. 17 is a chart diagram illustrating a programming operation of a nonvolatile memory device according to the embodiment, in which a horizontal axis indicates time and a vertical axis indicates voltage.

The embodiment is a combination of the above-described first embodiment and the sixth embodiment.

That is, as shown in FIG. 17, in the embodiment, by making the program time and the pass time agree with each other, the timing at which the program voltage is output is synchronized with the timing at which the pass voltage is output. As a result, it is possible to perform the programming of data still more efficiently. Moreover, the program voltage is higher than the pass voltage. The configuration, the operation, and the effect of the embodiment are the same as the configuration, the operation, and the effect of the previously described first embodiment, except for what has been just described above.

In the embodiment, by making the program time and the pass time agree with each other, it is possible to eliminate inconvenience in the programming operation such that the program voltage is applied to the selected word line WLs, yet the pass voltage is not applied to the non-selected word line WLns. That is, even when the program voltage is applied to the selected word line WLs, if the pass voltage is not applied to the non-selected word line WLns, the potential of the bit line cannot be transferred to the channel of the selected memory cell, and therefore the data cannot be programmed in the selected memory cell. As described above, by synchronizing the program time with the pass time, it is possible to simplify the control of the programming operation.

Moreover, by making the program voltage Vpgm and the pass voltage Vpass are fell at the same time, it is possible to improve the reliability of the memory cell without applying an excessive stress to the non-selected memory cells. Furthermore, it is possible to simplify the circuit configuration by using the same charge pump at the rise of the program voltage and the pass voltage.

The rise of the program time and the rise of the pass time may not be synchronized with each other. At least the pass voltage is shifted to the top period before the program voltage is only necessary to be shifted to the top period. As shown in FIG. 17, since the program voltage is higher than the pass voltage, the rising period of the program voltage often becomes longer than the rising period of the pass voltage. Therefore, by making the program voltage and the pass voltage rise at the same time, it is possible to make the pass voltage shifted to the top period before the program voltage is shifted to the top period, in a self-aligned manner.

Next, an eighth embodiment will be explained.

FIG. 18 is a chart diagram illustrating an erasing operation of a nonvolatile memory device according to the embodiment, in which a horizontal axis indicates time and a vertical axis indicates voltage.

The vertical axis of FIG. 18 indicates an absolute value of the voltage to be output between the active area and the word line.

As shown in FIG. 18, in an erasing operation of erasing data from the memory cell, an erase voltage is output in pulses between the active area and the word line for each BLK. At this time, the output of the erase voltage and the verification are repeated like in the case of the programming operation, and the later the pulse is to be output, the higher the erase voltage is set. Furthermore, the later the pulse is to be output, the longer the time during which the output of the erase voltage is maintained (hereinafter referred to as “erase time”).

For example, the following formulae (7) and (8) is set to be satisfied in continuous outputting the erase voltage not less than three times, when an erase voltage in the k-th output is set to Verase(k), a time in which the erase voltage is output is set to Terase(k), a constant voltage is set to Δv3, and a constant time is set to Δt3.

Verase(k)=Verase(k−1)+Δv3 (7)

Terase(k)=Terase(k−1)+Δt3 (8)

According to the embodiment, by controlling the erase time depending on the erase voltage, for the same reason as the reason for the first embodiment, it is possible to prevent the top period of the erase time from becoming too long, while realizing an efficient erasing operation. As a result, it is possible to realize a higher speed nonvolatile memory device. The configuration, the operation, and the effect of the embodiment are the same as the configuration, the operation, and the effect of the previously described first embodiment, except for what has been just described above.

The embodiment has been described in reference to the example in which the erase voltage Verase and the erase time Terase are changed according to the above formulae (7) and (8). However, the embodiment is not limited to this. When repeating the output of an erase voltage, it is only necessary to satisfy such condition that the later the pulse is to be output, the higher the erase voltage is set and the longer the erase time is set. Additionally, the above-described second to fifth embodiments may be applied to the embodiment.

According to the above-described embodiment, it is possible to realize a nonvolatile memory device which provides a high speed operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

For example, in each of the above-described embodiments, description is given in reference to the example in which the floating electrode is provided as a member for accumulating charges. However, the same effect can be obtained also by providing a charged trap film in the memory cell. That is, any memory device provided with a memory cell capable of storing data by accumulating charges is included in the scope of the invention as a matter of course.

What is claimed is:

1. A nonvolatile memory device, comprising:
a circuit for outputting a program voltage; and
a memory cell programmed data by being applied the program voltage,
the circuit outputting the program voltage so as to satisfy the following formulae, in the case of repeating an output of the program voltage n times (n is an integer not less than 3), when the program voltage in the k-th output (k is an integer not less than 2 and not greater than n) is set to Vpgm(k), a constant voltage is set as Δv1, a time in which the k-th output is continued is set to Tpgm(k), and a constant time is set as Δt1.
Vpgm(k)=Vpgm(k−1)+Δv1
Tpgm(k)=Tpgm(k−1)+Δt1

2. The device according to claim 1, wherein the circuit further outputs a program voltage after outputting the program voltage, so as to satisfy the following formulae.
Vpgm(k)>Vpgm(k−1)
Tpgm(k)=Tpgm(k−1)

3. The device according to claim 1, wherein
An NAND string including a plurality of the memory cells are connected in series,
when the circuit applies the program voltage to one of the plurality of memory cells, the circuit applies a pass voltage to anon-selected memory cells belonging to the NAND string, and
the circuit outputs the pass voltage so as to satisfy the following formula, when a time in which the pass voltage in the k-th time is output is set to Tpass(k).
Tpass(k)=Tpass(k−1)+Δt1

4. A nonvolatile memory device, comprising:
a circuit for outputting a program voltage; and
a memory cell programmed data by being applied the program voltage,
the circuit repeats an output of the program voltage a plurality of times, and
outputs in the plurality of times being divided into a plurality of groups along a time axis, and the output time is longer the among outputs which belongs to a later of the groups, while the output time is mutually equal among the outputs which belong to the same group.

5. A nonvolatile memory device, comprising:
a circuit for outputting a program voltage; and
a memory cell programmed data by being applied the program voltage,
the circuit setting the program voltage outputted later to be higher when the circuit repeats an output of the program voltage a plurality of times, and
outputs in the plurality of times being divided into a plurality of groups along a time axis, and the output time is shorter among the outputs which belongs to a later of the groups, while the output time i is mutually equal among the outputs which belong to the same group.

6. A nonvolatile memory device, comprising:
a circuit for outputting a program voltage; and
a memory cell programmed data by being applied the program voltage,
the circuit setting the program voltage outputted later to be higher when the circuit repeats an output of the program voltage a plurality of times,
each time in which the output is continued including a rising period in which the program voltage is increased, and a top period in which the program voltage is constant; and
a length of the top period is constant among the plurality of times of outputs.

7. The device according to claim 6, wherein a length of the rising period is constant among the plurality of times of outputs.

8. The device according to claim 6, further comprising:
a word line for transferring the program voltage to the memory cell; and
a potential measuring circuit connected to the word line,
the circuit detecting a transition time from the rising period to the top period based on a measurement result by the potential measuring circuit.

9. The device according to claim 6, further comprising:
a plurality of word lines for transferring the program voltage to each of a plurality of the memory cell;
an other memory cell;
an other word line for transferring the program voltage to the other memory cell; and
a potential measuring circuit connected to the other word line,
when the circuit outputs the program voltage to any of the plurality of word lines, the circuit outputting the program voltage also to the other word line, and detects a transition time from the rising period to the top period based on a measurement result by the potential measuring circuit.

10. The device according to claim 9, further comprising:
a pair of still other memory cells which are arranged on both sides of the other memory cell and are connected the other memory cell in series; and
a pair of still other word lines for transferring a voltage generated by the circuit to each of the still other memory cells,
when the circuit outputs the program voltage to any of the plurality of word lines, the circuit outputting a pass voltage which puts the semiconductor member in a conductive state, to the still other word lines.

11. A nonvolatile memory device, comprising:
a circuit for outputting a program voltage and a pass voltage; and
an NAND string including a plurality of memory cells connecting in series, which is programmed data by being applied the program voltage, and being applied the pass voltage,
when the circuit applies the program voltage to one of the plurality of memory cells, the circuit applying the pass voltage to a non-selected memory cells belonging to the NAND string, and
when the circuit repeats an output of the program voltage and the pass voltage a plurality of times,
the circuit setting the program voltage outputted later to be higher,
the circuit setting the pass voltage outputted later to be higher, and
the circuit setting a time in which the output of the pass voltage is continued to be longer.

12. The device according to claim 11, wherein
a time in which the program voltage is output agrees with a time in which the pass voltage is output.

13. The device according to claim 11, wherein a timing at which the program voltage is output is synchronized with a timing at which the pass voltage is output.

14. A nonvolatile memory device, comprising:
a circuit for outputting a program voltage and an erase voltage; and
a memory cell programmed data by being applied the program voltage and erased the data therefrom by being applied the erase voltage,
when the circuit repeats an output of the erase voltage a plurality of times,
the circuit setting the erase voltage outputted later to be higher, and
the circuit setting a time in which the output of the erase voltage is continued to be longer.
